(19) United States
(12) Patent Application Publication
(10) Pub. No.: US 2004/0140855 A1
(43) Pub. Date: Jul. 22, 2004

(54) Coolant test method and formulation

(75) Inventor: Buddy Don Gray, Dellrose, TN (US)

Correspondence Address: SEED INTELLECTUAL PROPERTY LAW GROUP PLLC, 701 FIFTH AVE, SUITE 6300, SEATTLE, WA, 98104-7092, US

(73) Assignee: TeknowSmartz Innovations/Technology Inc., North Vancouver (CA)

(21) Appl. No.: 10/639,615

(22) Filed: Aug. 11, 2003

Related U.S. Application Data
(60) Provisional application No. 60/402,437, filed on Aug. 9, 2002.

(51) Int. Cl. H03F 3/04

(52) U.S. Cl. 330/299

(57) ABSTRACT

A chemical formulation and the method of using said formulation for testing the ability of certain coolant treatment and additive formulations to actually perform certain aspects of the work for which they were intended. These certain aspects of work, for which the coolants ability to perform are tested, include the treated coolant's ability to remove scale from the treated system by inactivating, or otherwise rendering harmless, certain scale causing contaminants via chelation and sequestration. The invention further includes the method by which the testing is carried out.

### BACKGROUND OF THE INVENTION

1. Field of the Invention

The present invention relates generally to a method and chemical formulation. Specifically the invention relates to a formulation to test the ability of a coolant treatment or additive to do work. Specifically, the invention further relates to a method of using a formulation to perform testing. Specifically, the invention further relates to a method and chemical formulation that can test a coolant treatment's or additive's ability to perform work via chelation and sequestration of scale causing contaminants.

2. Description of the Related Art

Typically, prior art, as applicable to coolant treatment for heating, ventilation, and air conditioning (HVAC), has been to measure the total dissolved solids (TDS) that are present in the coolant or water. As more coolant treatment or additive is introduced into the coolant or water, the TDS increases. As the treatment or additive is removed from the coolant or water, either through blow down, precipitation, or some other means, and fresh make up water is added, the TDS goes down, indicating that more treatment or additive is required. The problem is, that contaminants in the water also contribute to the TDS of the coolant or water, and when the treatment or additive components start to precipitate, harmful scale normally starts to form, and the addition of more treatment or additive only serves to increase the precipitation. Thus, using TDS to determine when to add additional chemicals to a coolant is by no means tied to the ability of the chemicals in the coolant or water to do work.

Therefore, a need exist for both a method and formulation that will allow a coolant treatment additive's actual ability to do its intended work to be measured.

### BRIEF SUMMARY OF THE INVENTION

Accordingly, several objects and advantages of my invention are:

To determine the ability of a coolant treatment or additive to actually perform work.

To be quick and easy to use, without complex equipment or tedious chemical manipulation.

Further objects and advantages of the invention will become apparent from a consideration of the drawings and ensuing description.

The invention satisfies the need for a method and formulation that will quickly and easily determine the ability of a coolant treatment or additive to perform the actual work for which it was intended. This is accomplished by measuring the ability of the coolant treatment or additive to chelate and sequester.

### BRIEF DESCRIPTION OF THE DRAWINGS

FIGS. 1-5 illustrate a method and associated system for a coolant test method and formulation.

### DETAILED DESCRIPTION OF THE INVENTION

My invention is both a formulation and a method of testing the ability of a treatment or an additive in a coolant solution, or other water based solution, to actually perform the work of chelating, sequestering or otherwise rendering harmless, scale forming contaminants, such as calcium.

The formulation portion of the invention utilizes an indicator dye that reacts with calcium in water to produce one color, while in water without calcium, or with calcium that is bound chemically, the same dye produces a different color. In order for most dyes to function properly, there should be a source of hydroxide present. And if there is to be a color produced other than that produced, in water essentially free from calcium, then a source of calcium must also be present. Therefore the preferred indicator solution consists of:

(1) The indicator dye

(2) The hydroxide source

(3) The calcium source

(4) And, of course, water.

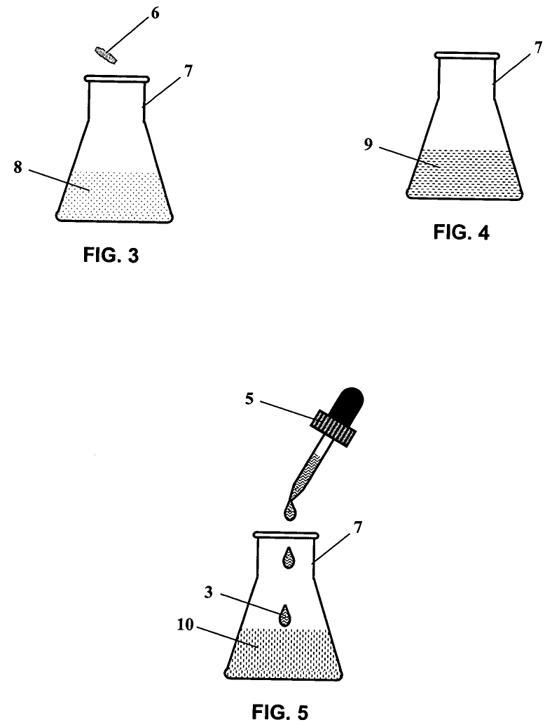

Since it is desirous to conserve weight, due to the costs to commercially ship the invention to points of use throughout the World, and being that water would, by many magnitudes, be the heaviest portion in the invention while also being the most commonly available and least expensive portion of the invention, the indicator solution, in the preferred embodiment, would be preferentially two separate components. One component, Part A, would consist of the indicator dye, the source of hydroxide, and the source of calcium. The second component, Part B, would be water that is essentially free of calcium, such water being readily available in any industrialized area of the World, and referred to as water 8 in FIG. 3.

With Part A being separated from the water, the physical amount of Part A required to do a test is so small as to make it essentially impractical to use. Therefore, an inert (to the reactions involved in this invention) extender is included in Part A so as to make measuring and utilization practical. In the preferred embodiment Part A is formed into a tablet 6 as shown in FIG. 3.

To make the indicator solution, a certain amount of Part A is mixed with a certain amount of water, Part B. In this embodiment the proper amount of Part A is preformed into tablet 6. When properly mixed, the indicator solution is ready to work and will be the calcium reacted color of the dye which, in a preferred embodiment, would be violet as indicated by the raw indicator solution 9 in FIG. 4.

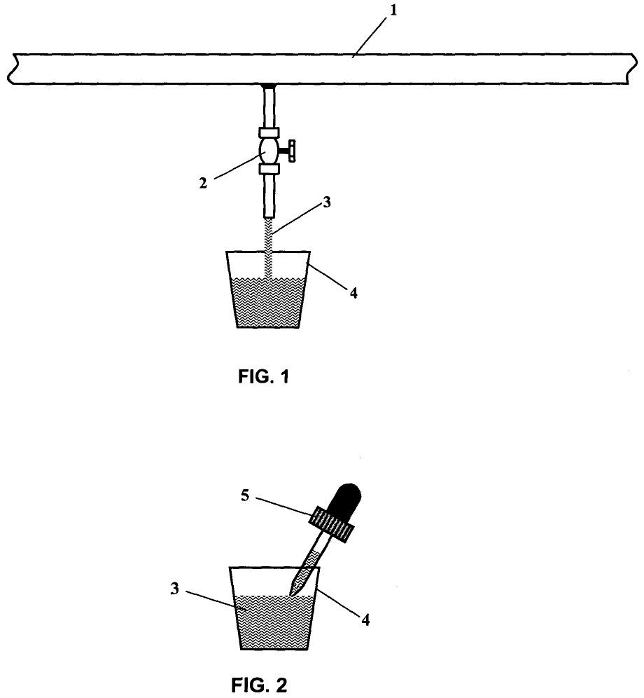

To perform an actual test, the afore mentioned indicator solution is first mixed, preferably in a suitable sized Erlenmeyer flask 7 to facilitate swirling and mixing. Next a sample of the coolant solution to be tested 3 is drawn from a suitable sample port 2 from the system under test 1 into a suitable sized beaker 4, or other non-contaminated container, as shown in FIG. 1. With a pipette 5, or other suitable instrument as shown in FIG. 2, the coolant solution 3 is titrated into the indicator solution 9, while swirling the flask 7, or otherwise mixing to ensure a proper reaction. As the coolant solution 3 is titrated into the indicator solution 9, if the coolant solution contains active chelation, sequestration, or some other active means to bind calcium then the calcium contained in the indicator solution is bound proportionally to the amount of active component in the coolant solution. As the calcium is bound by the coolant solution, the dye is freed from its reaction with the calcium and allowed to return to its natural, calcium free, desired color 10, in FIG. 5, which in a preferred embodiment would be blue. By knowing the amount of coolant solution 3 required to produce the desired color 10, the amount of active treatment or additive in the coolant solution 3 can be determined. This determination can then be used to determine the amount of additional treatment or additive that is to be added to the system 1 so as to maintain the proper level of active treatment or additive in the coolant solution 3.

While there are numerous indicator dyes that will produce various colors when free from calcium or reacted with calcium, and while there are various sources of calcium that can react with the indicator dye, and while there are various sources of hydroxide, Part A of a preferred embodiment of the invention can be made of the following:

Calcium Hydroxide in the ratio of from 0.1 to 10 parts by weight.

Eriochrome® Black T in the ratio of from 0.1 to 10 parts by weight.

Modified Corn Starch in the ratio of from 10 to 100 parts by weight.

And while there are various sources of water that is essentially free from calcium, Part B of a preferred embodiment is distilled water at a ratio of from 100 to 1,200 parts to 1 part of Part A by weight.

The following pages provide additional disclosure and illustrations of further embodiments of the invention and are incorporated herein in their entirety to form an integral part of the specification.

[image]

[image]

[image]

[image]

While the principles of the invention have now been made clear in the illustrated embodiments, there will be immediately obvious to anyone skilled in the art, many modifications of structure, arrangements, proportions, the elements, materials and components used in the practice of the invention and otherwise, which are particularly adapted for specific environments and operation requirements without departing from those principles. The invention is to be limited only by the scope of the appended claims and the equivalents thereof.

What is claimed is:

1. A method to determine the ability of a solution to bind cationic species, comprising:
sampling the solution; and
reacting the solution in a test solution to bind cationic species.

2. The method in claim 1 wherein said ability is determined by utilizing the sequestrating, chelating, or other means of binding cationic species power of the solution being tested to react with a cationic species in a test solution.

3. The method in claim 2 wherein a sample of said solution being tested is titrated into said test solution.

4. The method in claim 2 wherein said test solution changes color dependent upon the ability of said solution being tested to sequester, chelate, or otherwise bind cationic species.

5. The method in claim 2 wherein the quantity of an additive required to be added to said solution being tested to bring said solution back to within specification is determined.

6. The method in claim 1 wherein said solution is a coolant solution.

7. A formulation for determining the ability of a solution to bind cationic species, comprising an indicatory dye.

8. The formulation of claim 7 wherein the indicator dye is configured to react with a cationic species to change color from that when the cationic species is absent.

9. The formulation of claim 7 including a cationic species.

10. The formulation of claim 7 including a source of hydroxide.

11. The formulation of claim 7 including a solvent.

12. The formulation of claim 7 including two parts, part A and part B, and wherein part A comprises:
1. Said indicator dye
2. Said cationic species
3. Said hydroxide source
and part B comprises said solvent.

13. The formulation of claim 12 wherein Part A further includes a tabletizing binder allowing Part A to be formed as a tablet.

14. The formulation of claim 13 further including an extender.

15. The formulation of claim 14 wherein said extender performs as a tabletizing binder allowing Part A to be formed as a tablet.

16. The formulation of claim 9 wherein said cationic species is Calcium.

17. The formulation of claim 10 wherein said hydroxide source is Calcium Hydroxide.

18. The formulation of claim 11 wherein said solvent is water essentially free of Calcium.
